(19) United States
(12) Patent Application Publication
(10) Pub. No.: US 2013/0121520 A1
(43) Pub. Date: May 16, 2013

(54) PROTECTION STRUCTURE AND PORTABLE ELECTRONIC DEVICE USING SAME

(71) Applicants: Nai-Lin YANG, Shindian (TW); Bing ZHANG, Shenzhen City (CN); Shi-Feng WANG, Shenzhen City (CN)

(72) Inventors: Nai-Lin YANG, Shindian (TW); Bing ZHANG, Shenzhen City (CN); Shi-Feng WANG, Shenzhen City (CN)

(73) Assignees: FIH (Hong Kong) Limited, Kowloon (HK); SHENZHEN FUTAIHONG PRECISION INDUSTRY CO., LTD., ShenZhen City (CN)

(21) Appl. No.: 13/332,596

(22) Filed: Dec. 21, 2011

(30) Foreign Application Priority Data
Nov. 14, 2011 (CN) 201110359047.3

(51) Int. Cl. H04R 1/02; H05K 5/00

(52) U.S. Cl. 381/333; 361/679.01

(57) ABSTRACT

A portable electronic device includes a housing, a main board and a screen module fixed on the main board and located between the housing and the main board. The housing defines a resisting portion resisted against the main board. When an external force is out on the housing, the resisting portion can transmit the external force to the main board to protect the screen module from damage by the external force.

### TECHNICAL FIELD

The disclosure generally relates to portable electronic devices, and particularly to portable electronic devices incorporating a protection structure.

### DESCRIPTION OF THE RELATED ART

Portable electronic devices such as mobile phones include a housing, a main board mounted in the housing and a screen module fixed on the main board. The screen module may include a screen display and a fixing member connecting the screen display and the main board. However, the housing directly resists against the fixing member, and external forces against the housing may directly damage the screen display through the fixing member.

Therefore, there is room for improvement within the art.

### BRIEF DESCRIPTION OF THE DRAWINGS

Many aspects of the exemplary portable electronic device can be better understood with reference to the following drawings. The components in the various drawings are not necessarily drawn to scale, the emphasis instead being placed upon clearly illustrating the principles of the exemplary portable electronic device. Moreover, in the drawings, like reference numerals designate corresponding parts throughout the diagrams.

FIG. 1 is an exploded view of a portable electronic device according to an exemplary embodiment.

FIG. 2 is an assembled view of a partial component of the portable electronic device shown in FIG. 1.

FIG. 3 is an assembled view of the portable electronic device shown in FIG. 1.

FIG. 4 is a cross-sectional view of the portable electronic device shown in FIG. 3.

### DETAILED DESCRIPTION

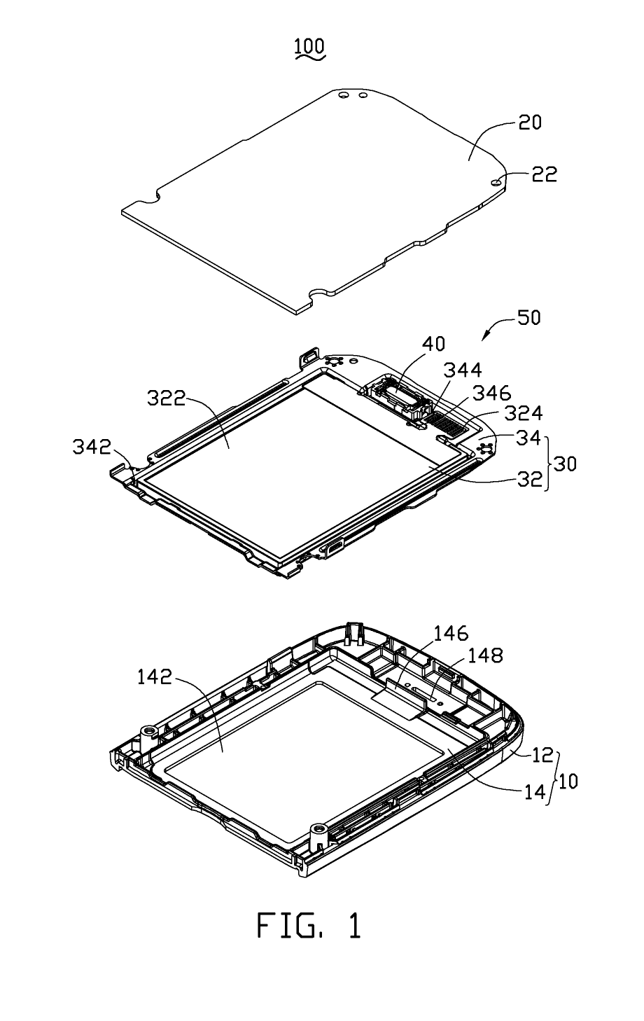

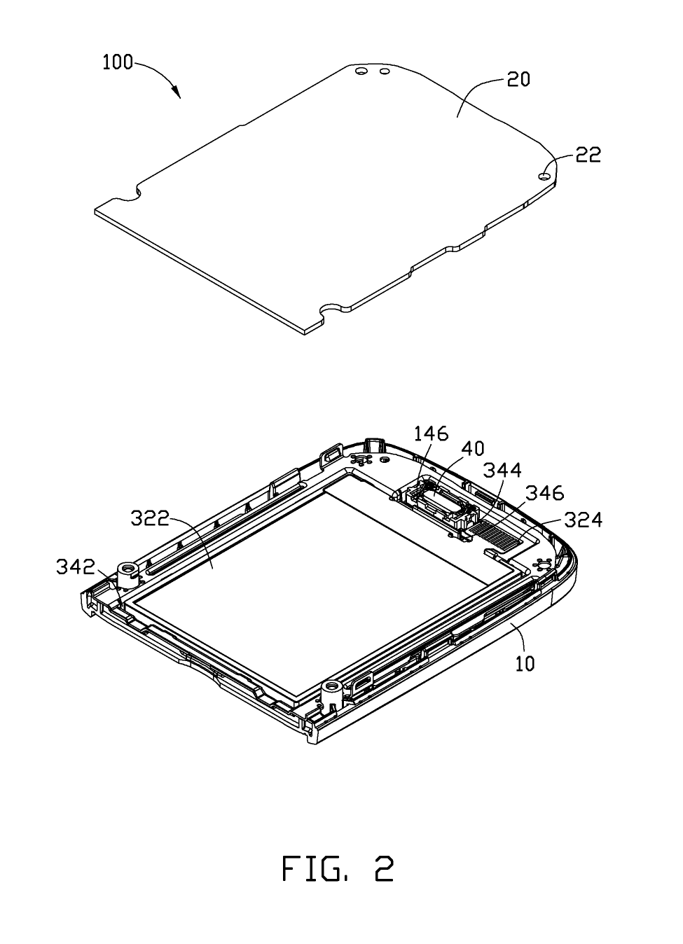

FIGS. 1 and 2 show an exemplary embodiment of a portable electronic device 100 such as a mobile phone, including a housing 10, a main board 20 mounted in the housing 10, a screen module 30 and a speaker 40, both the screen module 30 and the speaker 40 are fixed on the main board 20. The screen module 30 is secured between the housing 10 and the main board 20. The housing 10 and the main board 20 form a protection structure 50 for protecting the screen module 30.

The housing 10 includes a perimeter wall 12 and a main wall 14 connecting with the perimeter wall 12. The main wall 14 includes a screen display window 142, a resisting portion 146 and a sound port 148. The resisting portion 146 projects from the main wall 14 for resisting against the main board 20. The sound port 148 is located opposite to the speaker 40. The protection structure 50 defines a body, which is a part of the housing 10 with the resisting portion 146.

The screen module 30 includes a screen display 32 and a fixing member 34 fixing the screen display to the main board 20. The screen display 32 includes a screen display body 322 and electrical connectors 324 fixed on the screen display body 322. The electrical connectors 324 electrically connect the screen display body 322 to the main board 20.

The fixing member 34 defines a first retaining slot 342 for securing the screen display body 322, a second retaining slot 344 for securing the speaker 40 and a channel 346 communicating with the first retaining slot 342 and the second retaining slot 344.

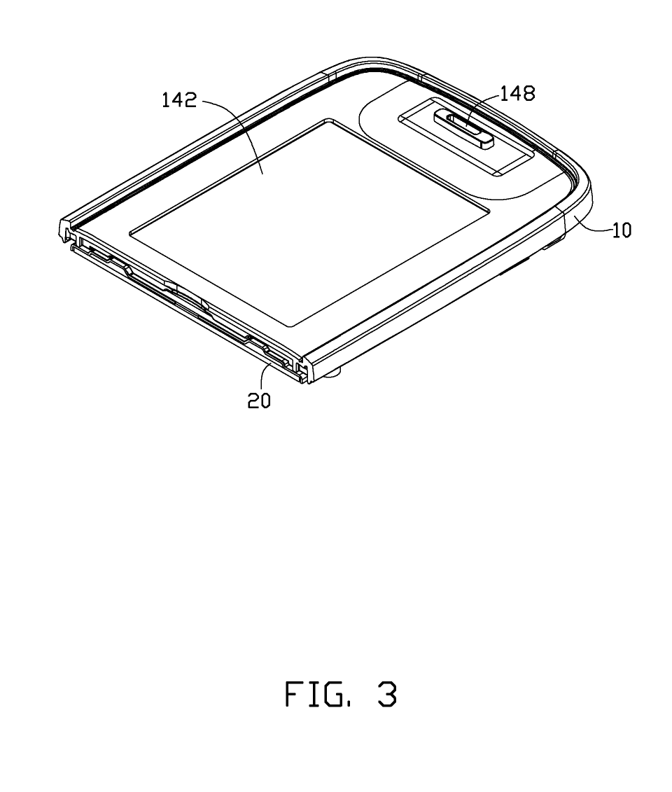

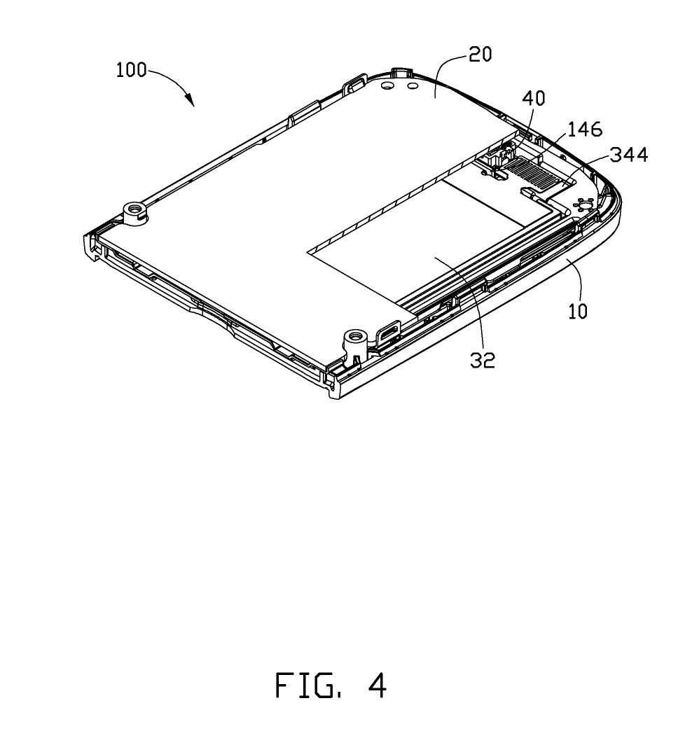

FIGS. 3 and 4, during assembly, the speaker 40 is fixed onto the main board 20. The fixing member 34 of the screen module 30 is fastened onto the main board 20, enabling the speaker 40 to be secured in the second retaining slot 344.

The resisting portion 146 of the housing 10 is inserted into the channel 346 until the resisting portion 146 resists against the main board 20. The second slot 344 is enclosed by the resisting portion 146 to define a sound chamber. At this time, the screen display window 142 faces the screen display 32, and the sound port 148 faces the speaker 40. In this case, the portable electronic device 100 is assembled when the main board 20 is fixed to housing 10.

In use, when an external force is applied to the housing 10, the housing 10 transmits the force to the main board 20 through the resisting portion 146, preventing the force from directly contacting the screen module 30, thereby preventing damage to the screen display 32.

It is to be understood, however, that even through numerous characteristics and advantages of the exemplary disclosure have been set forth in the foregoing description, together with details of the system and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A portable electronic device, comprising:
a housing defining a resisting portion;
a main board resisting against the resisting portion;
a screen module fixed on the main board and located between the housing and the main board;
wherein, when an external force is applied to the housing, the resisting portion can transmit the external force to the main board to protect the screen module from damage by the external force.

2. The portable electronic device as claimed in claim 1, wherein the screen module includes a screen display and a fixing member fixing the screen display to the main board.

3. The portable electronic device as claimed in claim 2, wherein the fixing member defines a first retaining slot, the screen display is secured in the retaining slot.

4. The portable electronic device as claimed in claim 3, wherein the portable electronic device further comprises a speaker fixed on the main board, the fixing member further defines a second retaining slot, the speaker is secured in the second retaining slot.

5. The portable electronic device as claimed in claim 4, wherein the fixing member further defines a channel connecting the first retaining slot and the second retaining slot, the resisting portion is resisted against the main board through the channel.

6. The portable electronic device as claimed in claim 5, wherein the second slot is enclosed with the resisting portion to define a sound chamber.

7. The portable electronic device as claimed in claim 4, wherein housing further defines a sound port opposite to the speaker.

8. The portable electronic device as claimed in claim 7, wherein the housing includes a screen display window opposite to the screen module.

9. A protection structure, comprising:
a body defining a resisting portion;
a main board resisting against the resisting portion;
a screen module fixed on the main board and located between the body and the main board;
wherein, when an external force is applied to the body, the resisting portion can transmit the external force to the main board to protect the screen module from damage by the external force.

10. The protection structure as claimed in claim 9, wherein the screen module includes a screen display and a fixing member fixing the screen display to the main board.

11. The protection structure as claimed in claim 10, wherein the fixing member defines a first retaining slot, the screen display is secured in the retaining slot.

12. The protection structure as claimed in claim 11, wherein the portable electronic device further comprises a speaker fixed on the main board, the fixing member further defines a second retaining slot, the speaker is secured in the second retaining slot.

13. The protection structure as claimed in claim 12, wherein the fixing member further defines a channel connecting the first retaining slot and the second retaining slot, the resisting portion is resisted against the main board through the channel.

14. The protection structure as claimed in claim 13, wherein the second slot is enclosed with the resisting portion to define a sound chamber.

15. The protection structure as claimed in claim 12, wherein body further defines a sound port opposite to the speaker.

16. The protection structure as claimed in claim 15, wherein the body includes a screen display window opposite to the screen module.
